(19) United States
(12) Patent Application Publication
(10) Pub. No.: US 2015/0097197 A1
(43) Pub. Date: Apr. 9, 2015

(54) FINFET WITH SIGMA CAVITY WITH MULTIPLE EPITAXIAL MATERIAL REGIONS

(71) Applicant: GLOBALFOUNDRIES Inc., Grand Cayman (KY)

(72) Inventors: Michael Ganz, Clifton Park, NY (US); Johannes M. van Meer, Newburgh, NY (US); Bharat V. Krishnan, Mechanicville, NY (US)

(73) Assignee: GLOBALFOUNDRIES Inc., Grand Cayman (KY)

(21) Appl. No.: 14/045,983

(22) Filed: Oct. 4, 2013

(51) Int. Cl. H01L 29/78; H01L 21/8234; H01L 29/66

(52) U.S. Cl. CPC H01L 29/785; H01L 29/66636; H01L 21/823418
USPC 257/77; 438/285

(57) ABSTRACT

Embodiments of the present invention provide an improved finFET and methods of fabrication. A sigma cavity is used with an n-type finFET to allow multiple epitaxial layers to be disposed adjacent to a finFET gate. In some embodiments, stacking faults may be formed in the epitaxial layers using a stress memorization technique.

### FIELD OF THE INVENTION

The present invention relates generally to semiconductor fabrication and, more particularly, to improved finFET devices and methods of fabrication.

### BACKGROUND

Semiconductor devices are increasing in layout density. Fin-type manufacturing techniques are employed to create non-planar structures on a semiconductor substrate. In these techniques, a semiconductor “fin” is formed, which facilitates formation of the gate of a device. Device density can be increased because the channel, source, and/or drain can be raised out of the semiconductor substrate, which reduces potential current leakage from the device. Accordingly, a device manufactured according to such a technique is often referred to as a fin-shaped field effect transistor (finFET). As integrated circuits continue to scale downward in size, the finFET is becoming an attractive device for use with smaller nodes (e.g., the 22 nm node and beyond). In a finFET, the channel is formed by a semiconductor fin, and a gate electrode is located on at least two sides of the fin. FinFETs have a wide variety of applications. It is therefore desirable to have improved finFET devices and methods of fabrication.

### SUMMARY

In a first aspect, the present invention provides a method of forming a semiconductor structure, comprising: forming a sigma cavity in a semiconductor substrate, wherein the sigma cavity is adjacent to a gate disposed on the semiconductor substrate; forming a first epitaxial material region in the sigma cavity; and forming a second epitaxial material region disposed on the first epitaxial material region.

In a second aspect, the present invention provides a semiconductor structure, comprising: a semiconductor substrate; a gate disposed on the semiconductor substrate; a sigma cavity formed in the semiconductor substrate adjacent to the gate; a first epitaxial material region formed in the sigma cavity; and a second epitaxial material region formed on the first epitaxial material region.

In a third aspect, the present invention provides a semiconductor structure, comprising: a semiconductor substrate; a gate disposed on the semiconductor substrate; a sigma cavity formed in the semiconductor substrate adjacent to the gate; a first epitaxial material region formed in the sigma cavity; a second epitaxial material region formed on the first epitaxial material region; and a stacking fault formed in the semiconductor structure, extending from the semiconductor substrate through the first epitaxial material region and the second epitaxial material region.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Often, similar elements may be referred to by similar numbers in various figures (FIGs) of the drawing, in which case typically the last two significant digits may be the same, the most significant digit being the number of the drawing figure (FIG.).

Features of this invention will be more readily understood from the following detailed description of the various aspects of the invention taken in conjunction with the accompanying drawings in which:

FIG. 1 shows a semiconductor structure at a starting point for illustrative embodiments;

FIG. 2 shows a semiconductor structure after a subsequent process step of forming a first epitaxial material region in accordance with illustrative embodiments;

FIG. 3 shows a semiconductor structure after a subsequent process step of forming a second epitaxial material region in accordance with illustrative embodiments;

FIG. 4 shows a semiconductor structure in accordance with an alternative embodiment of the present invention;

FIGS. 5A-5C show a semiconductor structure in accordance with another alternative embodiment of the present invention; and

FIG. 6 is a flowchart indicating process steps for embodiments of the present invention.

### DETAILED DESCRIPTION

Embodiments of the present invention provide an improved finFET and methods of fabrication. A sigma cavity is used with an n-type finFET to allow multiple epitaxial layers to be disposed adjacent to a finFET gate. In some embodiments, stacking faults may be formed in the epitaxial layers using a stress memorization technique.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

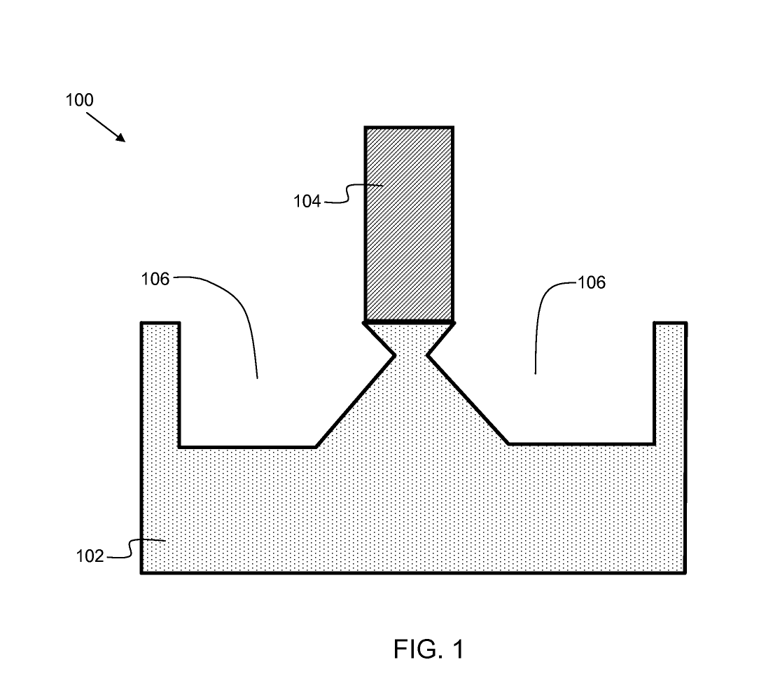

FIG. 1 shows a semiconductor structure 100 at a starting point for illustrative embodiments. Semiconductor structure 100 comprises a semiconductor substrate 102. In embodiments, semiconductor substrate 102 may be a silicon substrate. A gate 104 is disposed on the semiconductor substrate 102. In embodiments, the gate 104 may be comprised of polysilicon. In other embodiments, the gate 104 may be comprised of metal, and may be formed by a replacement metal gate (RMG) process. The gate 104 may be for an n-type field effect transistor, such as an n-type finFET. A thin gate dielectric layer (not shown) may be disposed between the gate 104 and the substrate 102. Sigma cavities 106 are formed in the substrate 102 adjacent to gate 104. Sigma cavities 106 may include one or more inclined sidewall surface areas that border the cavities 106, wherein the sidewalls may substantially correspond to specific crystal planes, such as (111) planes for a silicon material.

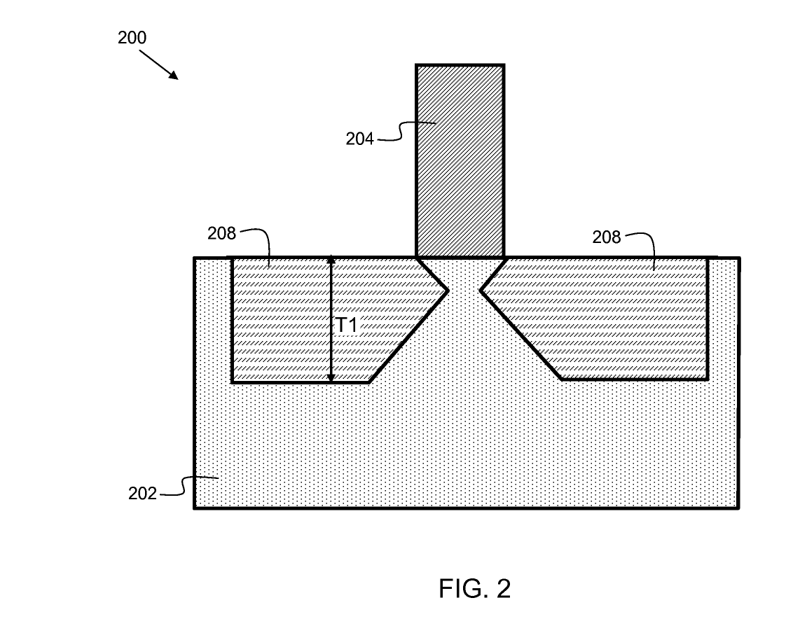

FIG. 2 shows a semiconductor structure 200 after a subsequent process step of forming a first epitaxial material region 208 in accordance with illustrative embodiments. As stated previously, similar elements may be referred to by similar numbers in various figures (FIGs) of the drawing, in which case typically the last two significant digits may be the same. For example, substrate 202 of FIG. 2 is similar to substrate 102 of FIG. 1. In embodiments, the first epitaxial material region 208 may include silicon carbon phosphorous (SiCP). The first epitaxial material region 208 has a thickness T1. In embodiments, T1 may range from about 30 nanometers to about 50 nanometers. SiCP provides stresses that can enhance carrier mobility, improving performance of a transistor. However, SiCP may not be an ideal material upon which to form contacts.

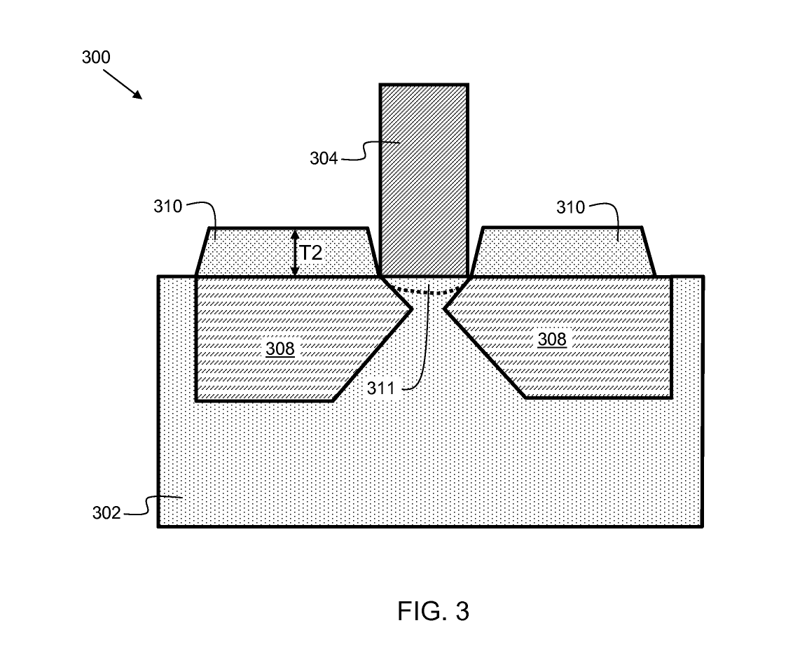

FIG. 3 shows a semiconductor structure 300 after a subsequent process step of forming a second epitaxial material region 310 in accordance with illustrative embodiments. In embodiments, the second epitaxial material region 310 may include silicon phosphorous (SiP). The second epitaxial material region 310 has a thickness T2. In embodiments, T2 may range from about 10 nanometers to about 20 nanometers. SiP does not provide significant stress, but does provide a better surface upon which to form contacts. Hence, the embodiment of FIG. 3 provides the benefit of increased carrier mobility by use of a stressor region (epitaxial material region 308) to impart stresses on channel region 311, and an improved contact surface provided by second epitaxial material region 310.

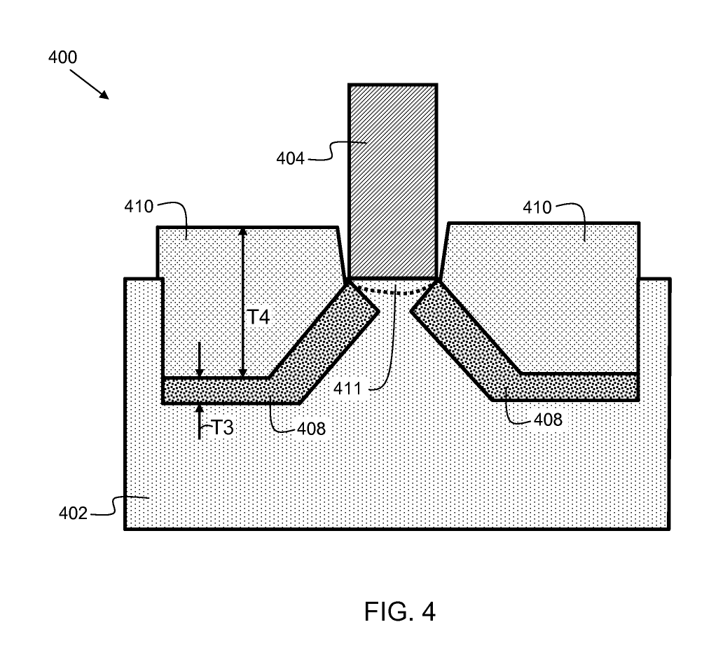

FIG. 4 shows a semiconductor structure 400 in accordance with an alternative embodiment of the present invention. In some cases, it may not be needed to apply stress to channel region 411. In this embodiment, the majority of the epitaxial material in the sigma cavities is from second epitaxial material region 410, which may be comprised of SiP. However, a thinner first epitaxial material region 408 is used to prevent dopants that are contained within the second epitaxial material region 410 from diffusing into substrate 402. In embodiments, the first epitaxial material region 408 may be comprised of silicon carbon (SiC), and the second epitaxial material region 410 may be comprised of SiP. The first epitaxial material region 408 has a thickness T3. The second epitaxial material region 410 has a thickness T4. In embodiments, T3 may range from about 5 nanometers to about 10 nanometers. In embodiments, T4 may range from about 30 nanometers to about 50 nanometers.

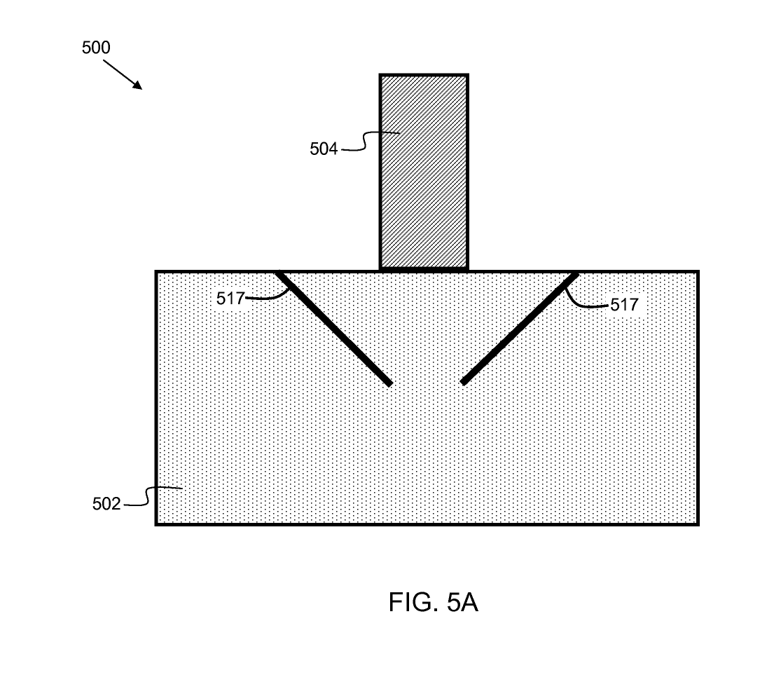

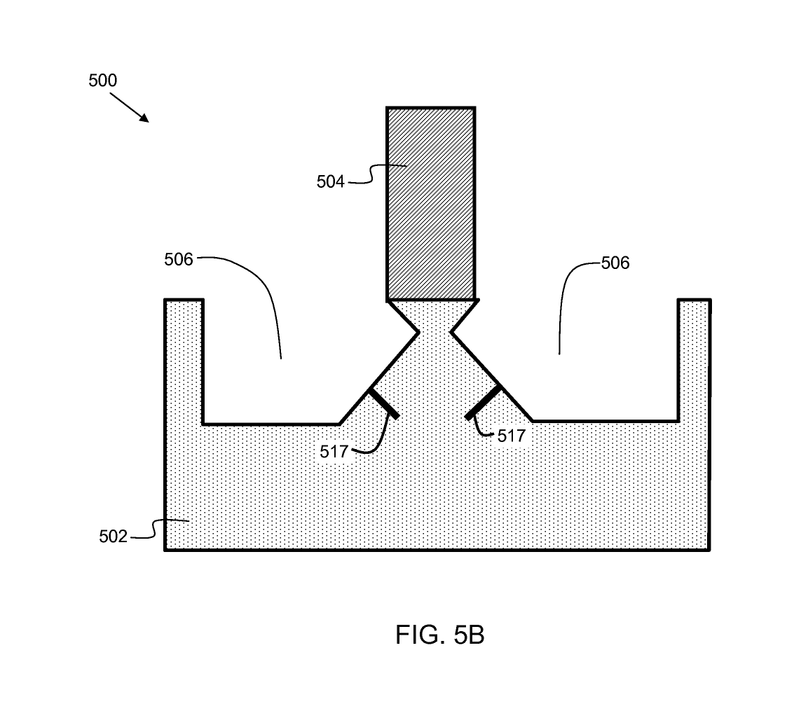

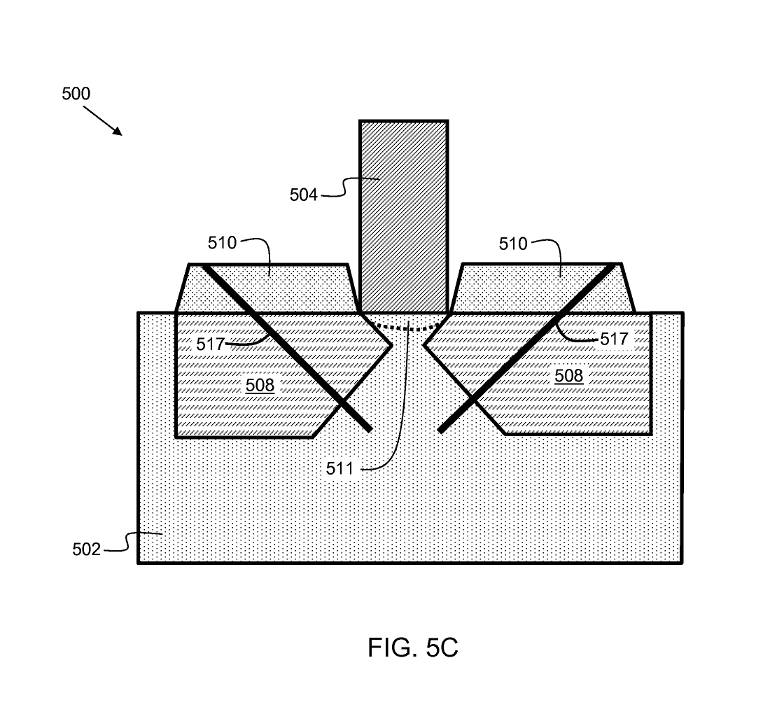

FIGS. 5A-5C show a semiconductor structure 500 in accordance with another alternative embodiment of the present invention. Structure 500 is similar to structure 300 of FIG. 3, with the addition of stacking faults 517. The stacking faults 517 serve to impart additional stress in channel 511, further enhancing carrier mobility and improving device performance. In embodiments, the stacking faults 517 may be formed using a stress memorization technique (SMT). The SMT may include forming spacers adjacent to the gate, followed by performing an amorphization implant. The amorphization implant “damages” silicon adjacent to the gate to convert it from crystalline silicon into amorphous silicon. Capping layers, which may include silicon oxide and/or silicon nitride layers are then deposited over the structure. A subsequent anneal then converts the amorphous silicon back to crystalline silicon. The mechanical constraints of the capping layers cause stacking faults to form in the silicon substrate, and the stacking faults impart additional stress on the channel disposed underneath gate 504. The SMT process may be performed prior to formation of sigma cavities, resulting in the structure shown in FIG. 5A. A portion of the stacking faults 517 remain after formation of the sigma cavities 506, as shown in FIG. 5B. The stacking faults are present in the epitaxial regions that are subsequently formed on the sigma cavities, as shown in FIG. 5C, due to the properties of epitaxial growth. Hence, the embodiment of FIG. 5C provides improved device performance by a combination of sigma cavity, epitaxial stressor regions (first epitaxial material region 508), epitaxial contact regions (second epitaxial material region 510), and stacking faults 517. As shown in FIG. 5C, the stacking faults 517 extend from the semiconductor substrate 502, through the first epitaxial material region 508 and the second epitaxial material region 510. In embodiments, the structure of FIG. 5C may be an n-type finFET.

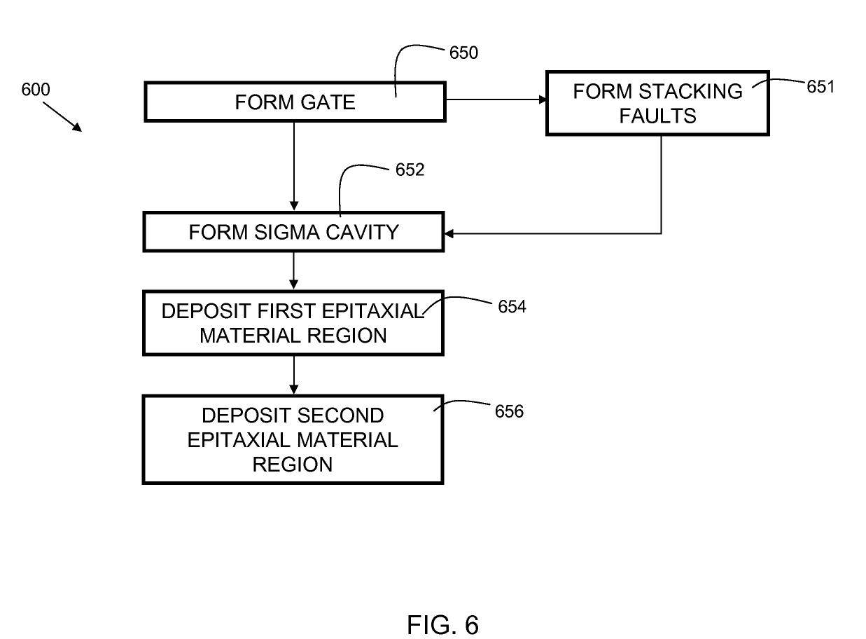

FIG. 6 is a flowchart 600 indicating process steps for embodiments of the present invention. In process step 650, a gate is formed on a semiconductor substrate. In process step 652, sigma cavities are formed in the substrate adjacent to the gate. In process step 654, a first epitaxial material region is formed in the sigma cavities. In process step 656, a second epitaxial material region is formed on the first epitaxial material region. Optionally, after step 650, stacking faults may be formed in process step 651, prior to formation of the sigma cavity in process step 652. The stacking faults may be formed using a stress memorization technique (SMT) process.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A method of forming a semiconductor structure, comprising:
forming a sigma cavity in a semiconductor substrate, wherein the sigma cavity is adjacent to a gate disposed on the semiconductor substrate;
forming a first epitaxial material region in the sigma cavity, wherein a top surface of the first epitaxial material region is substantially planar with a top surface of the semiconductor substrate; and
forming a second epitaxial material region disposed on the first epitaxial material region.

2. The method of claim 1, wherein forming a first epitaxial material region comprises forming a SiCP region.

3. The method of claim 2, wherein forming a second epitaxial material region comprises forming a SiP region.

4. The method of claim 3, wherein forming a SiCP region comprises forming a SiCP region having a thickness ranging from about 30 nanometers to about 50 nanometers.

5. The method of claim 4, wherein forming a SiP region comprises forming a SiP region having a thickness ranging from about 10 nanometers to about 20 nanometers.

6. The method of claim 1, wherein forming a first epitaxial material region comprises forming a SiC region.

7. The method of claim 6, wherein forming a second epitaxial material region comprises forming a SiP region.

8. The method of claim 7, wherein forming a SiC region comprises forming a SiC region having a thickness ranging from about 5 nanometers to about 10 nanometers.

9. The method of claim 8, wherein forming a SiP region comprises forming a SiP region having a thickness ranging from about 30 nanometers to about 50 nanometers.

10. The method of claim 5, further comprising forming a stacking fault in the SiCP region and the SiP region.

11. The method of claim 10, wherein forming a stacking fault comprises performing a stress memorization technique (SMT) process.

12. A semiconductor structure, comprising:
a semiconductor substrate;
a gate disposed on the semiconductor substrate;
a sigma cavity formed in the semiconductor substrate adjacent to the gate;
a first epitaxial material region formed in the sigma cavity, wherein a top surface of the first epitaxial material region is substantially planar with a top surface of the semiconductor substrate; and
a second epitaxial material region formed on the first epitaxial material region.

13. The semiconductor structure of claim 12, wherein the first epitaxial material region is comprised of SiCP.

14. The semiconductor structure of claim 13, wherein the second epitaxial material region is comprised of SiP.

15. The semiconductor structure of claim 14, wherein the first epitaxial material region has a thickness ranging from about 30 nanometers to about 50 nanometers.

16. The semiconductor structure of claim 15, wherein the second epitaxial material region has a thickness ranging from about 10 nanometers to about 20 nanometers.

17. The semiconductor structure of claim 12, wherein the first epitaxial material region is comprised of SiC.

18. The semiconductor structure of claim 17, wherein the second epitaxial material region is comprised of SiP.

19. A semiconductor structure, comprising:
a semiconductor substrate;
a gate disposed on the semiconductor substrate;
a sigma cavity formed in the semiconductor substrate adjacent to the gate;
a first epitaxial material region formed in the sigma cavity, wherein a top surface of the first epitaxial material region is substantially planar with a top surface of the semiconductor substrate;
a second epitaxial material region formed on the first epitaxial material region; and
a stacking fault formed in the semiconductor structure, extending from the semiconductor substrate through the first epitaxial material region and the second epitaxial material region.

20. The semiconductor structure of claim 19, wherein the first epitaxial material region comprises SiCP, and wherein the second epitaxial material region comprises SiP.
